(19) United States
(12) Patent Application Publication
(10) Pub. No.: US 2006/0207973 A1
(43) Pub. Date: Sep. 21, 2006

(54) Apparatus adapted to engrave a label and related method

(76) Inventor: Sang-Bong Lee, Dalseo-gu (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/384,433

(22) Filed: Mar. 21, 2006

(30) Foreign Application Priority Data
Mar. 21, 2005 (KR) 2005-0023055

(51) Int. Cl. C23F 1/00; C03C 15/00; H01L 21/306

(52) U.S. Cl. 216/94; 216/84; 156/345.1; 156/345.24; 216/2

(57) ABSTRACT

An apparatus adapted to engrave a label and a related method for engraving a label are disclosed. The apparatus includes a laser diode adapted to emit a laser beam and heat-exchanging member adapted to adjust the temperature of the laser diode. The method includes measuring a present energy level of the laser beam emitted from a laser diode, calculating a temperature compensation value, adjusting the temperature of the laser diode to a reference temperature in accordance with the temperature compensation value, and emitting a laser beam from the laser diode having the reference temperature.

### BACKGROUND OF THE INVENTION

1. Field of the Invention

Embodiments of the invention relate to an apparatus adapted to engrave a label and a method for engraving a label. More particularly, embodiments of the invention relate to a method for engraving a label on a wafer, such as those used as semiconductor substrates, and an apparatus adapted to engrave a label on a wafer using the method.

This application claims priority to Korean Patent Application No. 2005-0023055, filed on Mar. 21, 2005, the subject matter of which is hereby incorporated by reference in its entirety.

2. Description of Related Art

Over time, the size and integration density of semiconductor devices have increased in order to meet a rising demand greater quantities data manipulation at higher speeds. Semiconductor devices are manufactured on a wafer using a complex series of processes comprising, for example, a photolithography process, an etching process, a deposition process, a diffusing process, an ion implantation process, a metal deposition process, etc. This complex series of processes will hereinafter be referred to as a “manufacturing method.”

Each wafer passing through the manufacturing method must be carefully managed. Such management is typically accomplished by resort to a label engraved on the wafer. The label may include, for example, a product number and/or a processing lot number. Before each wafer passes through a particular process in the manufacturing method, its label is read and the information on the label correlated with the process expectations (e.g., process order, etc.) defined by the manufacturing method. Only if the label information properly corresponds to the current process (i.e., the process to next be performed on the wafer), will the current process be performed on the wafer. Thus, the label plays an important role in management of individual wafers passing through the manufacturing method.

In general, a label comprises a combination of alphanumeric characters and/or other symbols. Conventionally, labels have been engraved on wafers using a laser beam. However, this conventional approach to the formation of labels on wafers suffers from a number of problems. Several of these problems will be described in relation to an exemplary, conventional method of engraving a label on a wafer, as illustrated in FIGS. 1 through 3.

FIG. 1 is a plan view illustrating a portion of a conventional wafer adapted for use as a semiconductor substrate on which a label has been engraved. FIG. 2 is a scanning electron microscope (SEM) picture showing dots from the label of FIG. 1, wherein the label of FIG. 1 is normally formed. FIG. 3 is an SEM picture showing dots from the label of FIG. 1, wherein the label of FIG. 1 is abnormally formed.

Referring to FIG. 1, a label L is engraved on an outer edge portion of a wafer W. Where wafer W has a flat zone, label L may be engraved on the flat zone.

Label L is commonly engraved using optical energy (hereafter, generally referred to as “light”) provided by an ultraviolet ray or a laser beam. To engrave label L on the upper surface of wafer W, the applied light sequentially etches the upper surface of wafer W with a pattern of small dots. In combination, this pattern of small dots forms the characters and symbols of label L.

Where the light is properly applied to form label L, normal dots, like dot D1 in FIG. 2, are formed. However, where the light is improperly applied to form label L, abnormal dots, like dot D2 in FIG. 3, are formed.

The formation of abnormal dots is not merely a matter of aesthetics. Indeed, a label formed from abnormal dots may appear perfectly normal to the naked eye. It is only when viewed in a magnified state that abnormal dots may be discerned. However, the formation of an abnormal dot generally occurs when the light applied to wafer W has an energy level ill-suited (e.g., too high, wrong frequency, etc.) to the task of forming the label. That is, label engraving is accomplished by selectively burning portions of the wafer surface in a controlled manner. Abnormal dots are formed when the wafer surface is overheated, or when too much of the wafer surface is heated during the label making process.

Assuming for the moment that a laser beam is used to produce the label, the amount of optical energy imparted by the laser beam will vary with the temperature of a laser diode emitting the laser beam. When properly controlled to form normal dots D1, the applied optical energy forms label L without otherwise damaging the wafer surface.

However, when abnormal dots D2 are formed on the wafer, its surface may be fractured, thereby producing minute particles. Thereafter, when the wafer is polished in a chemical mechanical polishing (CMP) process, for example, these particles may scratch and further damage the wafer surface.

To overcome this particular problem, a method of labeling a semiconductor wafer using deionized water is disclosed in Korean Patent Laid-Open Publication No. 1995-0015581. Further, a method and an apparatus for labeling a wafer using an aperture, which controls a permeation extend of a laser beam, is disclosed in Japanese Patent Laid-Open Publication No. 2001-138076. However, in both of these disclosures, the path of the engraving laser beam is merely controlled (e.g., partially changed or blocked) without any active control or even monitoring of the actual energy level of the laser beam. As a result, failures in the formation of labels still occur due to variations in the temperature of the laser diode producing the engraving laser beam.

It should be noted that wafers, such as those for use as a semiconductor device substrate, are very expensive. They have become more so in recent years with the use of ever larger wafer sizes in contemporary manufacturing operations. Thus, when a wafer damaged due to the problems associated with the formation of a label, a significant amount of time and money is lost. The problems mentioned above must be solved in view of the current development trends for semiconductor devices, which are all oriented toward higher integration densities and greater manufacturing capacity.

### SUMMARY OF THE INVENTION

Embodiments of the present invention provide a method of effectively engraving a label by maintaining an energy level of a laser beam at a constant level. Embodiments of the present invention also provide an apparatus for performing the method.

In an example embodiment of the present invention provides a method of engraving a label on an object comprising measuring a present energy level of a first laser beam emitted from a laser diode, wherein the present energy level corresponds to a present output power of the laser diode, and calculating a temperature compensation value. The method further comprises, adjusting the temperature of the laser diode to the reference temperature in accordance with the temperature compensation value, and irradiating a second laser beam from the laser diode onto a semiconductor substrate to engrave the label on the semiconductor substrate, wherein the second laser beam has the reference output power. The method still further comprises repeating the previously-mentioned steps of the method.

In an example embodiment of the present invention provides an apparatus adapted to engrave a label on an object comprising a light source member comprising a laser diode adapted to emit a first laser beam; a measuring member adapted to measure a present energy level of the first laser beam, wherein the present energy level corresponds to a present output power; and, a processing member adapted to compare the present energy level with a reference energy level to calculate a temperature compensation value for the laser diode, wherein the reference energy level is an energy level of a reference laser beam emitted from the laser diode at a reference temperature. The apparatus further comprises a heat-exchanging member adapted to adjust a temperature of the laser diode to the reference temperature in accordance with the temperature compensation value; and, a projection member adapted to project the first laser beam onto a semiconductor substrate to engrave the label on the semiconductor substrate.

### BRIEF DESCRIPTION OF THE DRAWINGS

Example embodiments of the present invention will now be described with reference to the accompanying drawings, in which like reference numerals refer to like or similar elements throughout. In the drawings:

FIG. 1 is a plan view illustrating a portion of a semiconductor substrate on which a label is engraved in accordance with a conventional method;

FIG. 2 is an electron microscopic picture showing normally formed dots adapted to use in the formation of the label of FIG. 1;

FIG. 3 is an electron microscopic picture showing abnormally formed dots;

FIG. 4 is a perspective view illustrating a system adapted to engrave a label in accordance with an example embodiment of the present invention;

FIG. 5 is a schematic view further illustrating the system of FIG. 4; and

FIG. 6 is a graph showing a relationship between input current and output power for the laser diode of FIG. 5.

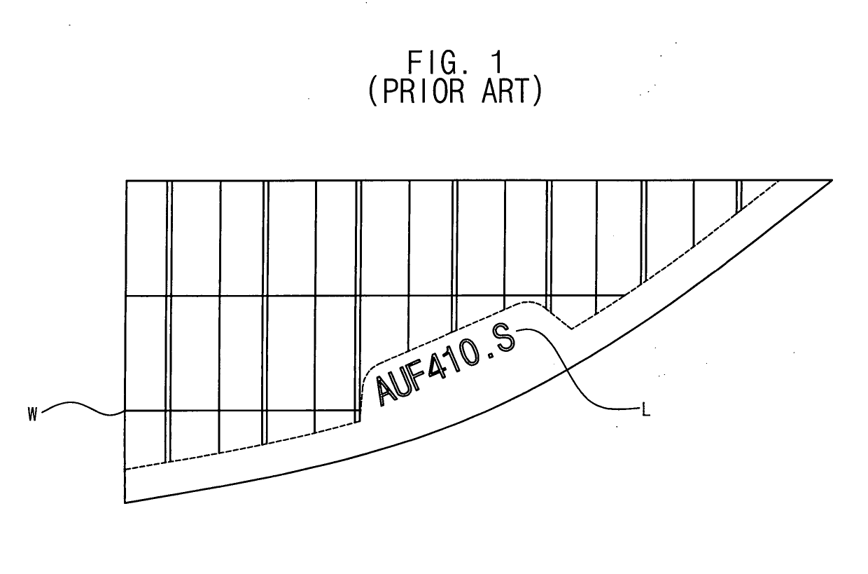

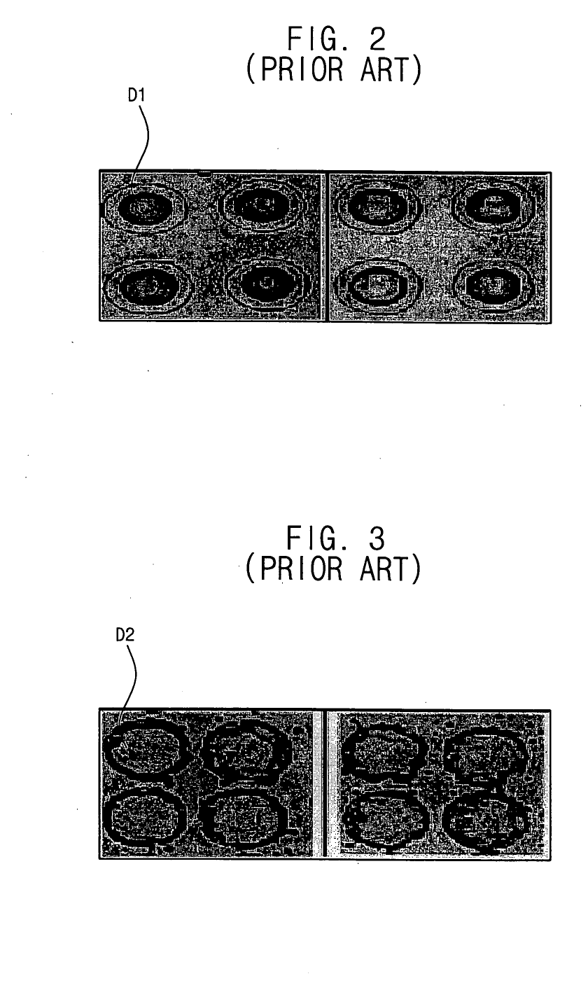

### DESCRIPTION OF THE EXAMPLE EMBODIMENTS

Several example embodiments of the present invention will now be described with reference to the accompanying drawings. These embodiments are presented as teaching examples. The scope of the present invention is not limited to only the disclosed embodiments, but is defined by the following claims.

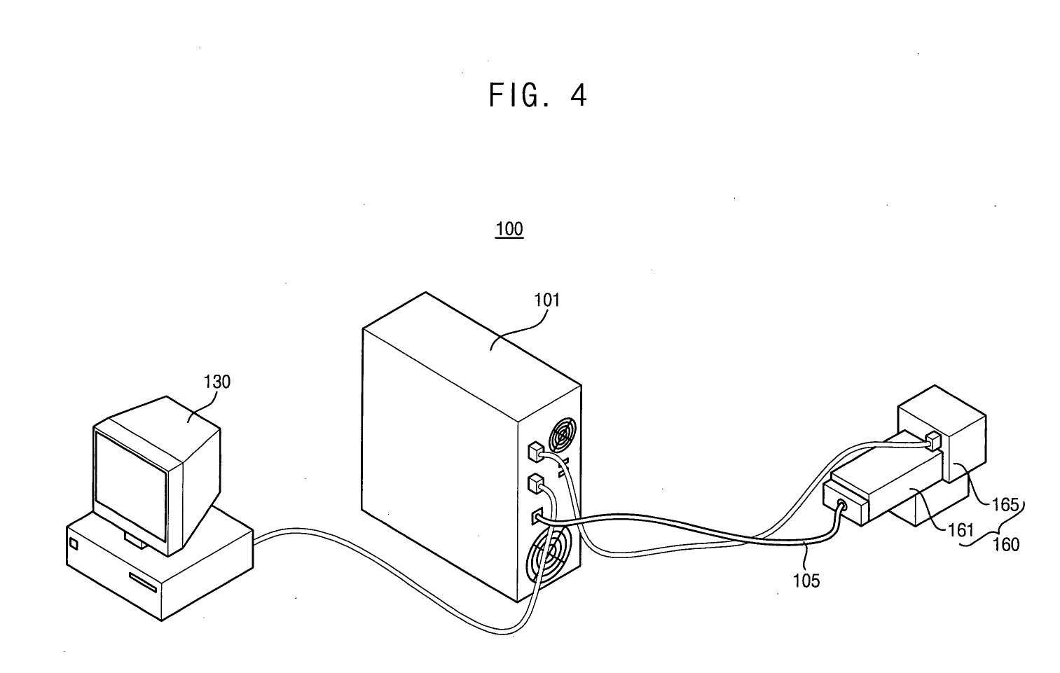

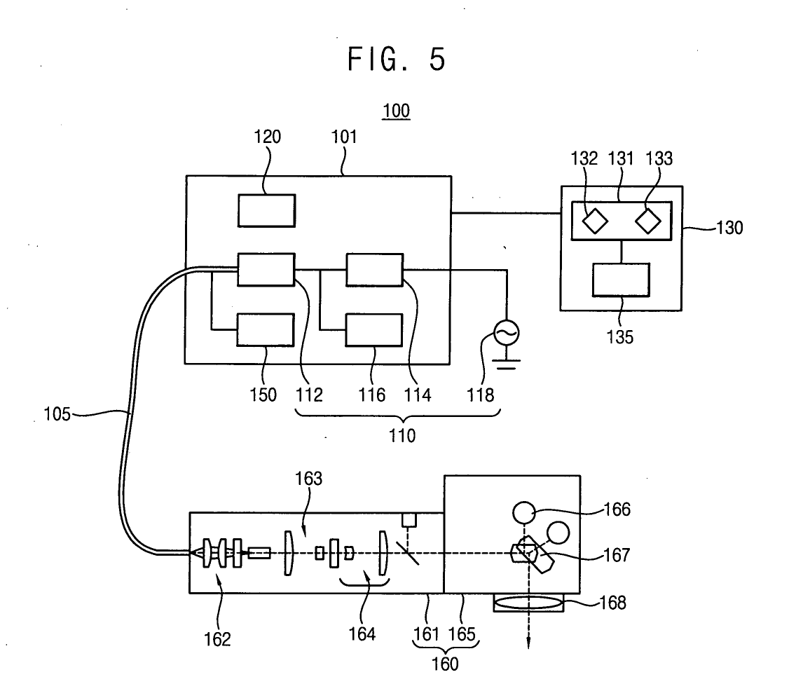

FIG. 4 is a perspective view illustrating a system adapted to engrave a label in accordance with an example embodiment of the present invention. FIG. 5 is a related schematic view further illustrating the system of FIG. 4.

In the illustrated example of FIGS. 4 and 5, an apparatus 100 adapted to engrave a label comprises a light source member 110, a measuring member 120, a processing member 130, a heat-exchanging member 150, and a projection member 160.

The light source member 110 is adapted to emit a laser beam, which is adapted to engrave a label on an object such as a semiconductor substrate. The light source member 110 comprises a laser diode 112, an internal power supply 114, and a controller 116. The internal power supply 114 is connected to an external power supply 118.

In the illustrated example, the laser diode 112 is a P-N junction semiconductor device adapted to generate a laser beam when a forward current is applied to it. A single channel structure or a multi-channel structure cathode type diode, and a single channel structure or a multi-channel structure anode type diode may be selected for use as the laser diode 112. The laser diode 112 may emit a laser beam having a wavelength of hundreds to thousands of nanometers, but in one embodiment the wavelength of the laser beam is preferably about 600 nanometers to about 1,000 nanometers.

The internal power supply 114 is adapted to apply an operating voltage to the laser diode 112. To obtain the operating voltage, the internal power supply 114 precisely adjusts a voltage provided by the external power supply 118. The internal power supply 114 may provide a voltage of several to tens of volts to the laser diode 112 as the operation voltage. For example, the internal power supply 114 may provide about 2 to about 5 volts to the laser diode 112.

The controller 116 is adapted to adjust an energy level of the laser beam emitted from the laser diode 112. The controller 116 adjusts the amount of a current provided from the internal power supply 114 to the laser diode 112 using a variable resistance. An amount of a current that the controller 116 applies to the laser diode 112 may vary, but the controller 116 may apply a current of no more than about tens of milliamperes to the laser diode 112. For example, though the amount of the current that the controller 116 applies to the laser diode 112 may vary, the controller 116 may apply a current of no more than about 50 milliamperes to the laser diode 112.

The measuring member 120 is adapted to measure the present energy level (i.e., the actual energy level) of the laser beam emitted from the laser diode 112, which is measured in Joules. The measuring member 120 is located adjacent to a path of the laser beam. Though the measuring member 120 may interfere with the path of the laser beam, the measuring member 120 will not completely cut off the path of the laser beam. Thus, the present energy level of the laser beam may be measured during the process for making the label.

The measuring member 120 comprises a photometer adapted to generate a photocurrent corresponding to the present energy level of the laser beam. The measuring member 120 converts the photocurrent into a voltage representing the present energy level of the laser beam.

The processing member 130 is adapted to calculate a temperature compensation value for the laser diode 112 by comparing the present energy level of the laser beam provided by the measuring member 120 with a reference energy level of the laser beam. The processing member 130 comprises a memory module 131 and a calculating module 135.

As used herein, “input current” refers to a current value that corresponds to an amount of a current applied to a laser diode just after a laser beam is emitted from the laser diode. In addition, as used herein, “output power” refers to a data value corresponding to an amount of a power output by the laser beam emitted from a laser diode. As used hereinafter with reference to the illustrated embodiments, “input current” and “output power” refer to the input current of the laser diode 112 and the amount of power output by the laser beam emitted by the laser diode 112, respectively.

The memory module 131 stores the input current. The memory module 131 also stores a calculation program adapted to perform calculations in accordance with a relationship between the input current, the output power, and a temperature of the laser diode 112. In the illustrated example, the memory module 131 comprises a data memory portion 132 and a program memory portion 133.

The memory module 131 is electrically coupled to the controller 116 of the light source member 110 in order to receive the input current in real-time and store the input current in the data memory portion 132.

The calculation program is stored in the program memory portion 133 of the memory module 131. In one embodiment, the calculation program calculates the output power of the laser beam in accordance with variations in the temperature of the laser diode 112 while the input current is continuously changed in relation to a database storing calculated output power values. The database may be stored in the data memory portion 132 of the memory module 131. Further, the calculation program may be further adapted to provide a graphical representation of the database.

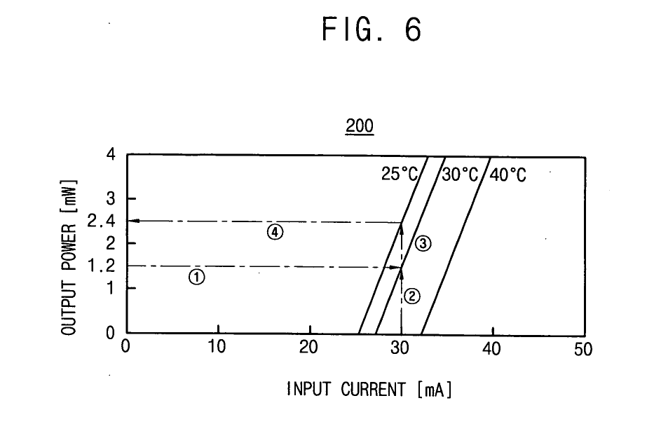

FIG. 6 is an example graph illustrating a relationship between an input current and an output power.

Referring to FIG. 6, a characteristic graph 200 of the laser diode represents the relationship between input current and output power in accordance with the temperature of the laser diode 112. The output power of the laser beam emitted from the laser diode 112 corresponds to an energy level of the laser beam. Particularly, the output power of the laser beam is measured in Watts (W), and the energy level of the laser beam is measured in Joules (J). Thus, the power output of the laser diode 112 represents the amount of energy emitted by the laser beam each second (J/s).

While the temperature of the laser diode 112 is constant, the output power increases in proportion to an increase in the input current. However, while the input current has a constant value, the output power decreases in proportion to an increase in the temperature of the laser diode 112. The preceding characteristics of the laser diode 112 are represented in the graph in FIG. 6, in which the output power and the input current vary linearly at any one temperature of laser diode 112. Thus, the characteristics of the laser diode 112 may be represented by an equation such as a linear equation (i.e., an equation that may be adapted for calculating a slope). Therefore, when any two of the three pieces of data used in characteristic graph 200 (i.e., the input current, the output power, and the temperature of the laser diode 112) are measured, the remaining piece of data may be calculated using the linear equation for the laser diode 112. For example, when input current and output power are measured, the temperature of the laser diode 112 may be calculated easily using the calculation program.

The laser diode 112 may be a semiconductor device having a relatively small size and a high sensitivity to its surroundings. Thus, due to the temperature characteristics of the laser diode 112, it is difficult to directly measure the present temperature (i.e., the actual temperature) of the laser diode 112 precisely. However, in this example embodiment of the present invention, the present temperature of the laser diode 112 is indirectly measured (i.e., calculated) using characteristic graph 200 for the laser diode 112 or using the calculation program. As used herein, the process of “using” a graph may comprise using the data that the graph represents.

The indirectly measured present temperature of the laser diode 112 is converted into a first electrical signal. The first electrical signal is then provided to the calculating module 135. The calculating module 135 compares the first electrical signal corresponding to the indirectly measured present temperature of the laser diode 112 with a reference temperature stored in the memory module 131 to calculate the temperature compensation value for the laser diode 112. The temperature compensation value is a second electrical signal adapted to indicate the difference between the present temperature of the laser diode 112 and the reference temperature stored in the memory module 131. The temperature compensation value is provided to the heat-exchanging member 150 which adjusts the temperature of the laser diode 112 to the reference temperature.

The heat-exchanging member 150 heats or cools the laser diode 112 in accordance with the temperature compensation value provided by the calculating module 135 to adjust the temperature of the laser diode 112 to the reference temperature. In the illustrated embodiment, the heat-exchange member 150 may comprise a chiller and/or a heating pump that provides a heat-exchange function in relation to the laser diode 112 using an operation fluid or an operation gas. The temperature of the laser diode 112 increases in proportion to the operation time of the laser diode 112. Thus, the heat-exchanging member 150 mainly cools the laser diode 112 using a coolant such as, for example, a chlorofluorocarbon (CFC) gas, a perfluoro carbon (PFC) gas, a hydrofluoro carbon (HFC) gas, etc. Additionally, the heat-exchanging member 150 may further comprise a fan adapted to circulate air in the label engraving apparatus 100.

The process described above for adjusting the temperature of the laser diode 112 may be performed at predetermined intervals to constantly maintain the temperature of the laser diode 112 at the reference temperature. Alternatively, the process for adjusting the temperature of the laser diode 112 may be carried out to constantly maintain the temperature of the laser diode 112 at the reference temperature in real-time.

One difference between the label engraving apparatus of the present example embodiment and a conventional label engraving apparatus is that the conventional label engraving apparatus automatically sets an optimal temperature for the laser diode. The temperature of the laser diode is then compensated to adjust the temperature of the laser diode to the automatically set optimal temperature regardless of the difference between the present temperature of the laser diode and the automatically set optimal temperature (i.e., regardless of the variation in the temperature of the laser diode). On the contrary, in this exemplary embodiment of the present invention, after a working temperature for the laser diode is set in the label engraving apparatus, the laser diode 112 is heated or cooled to maintain that working temperature. The working temperature is a temperature for the laser diode 112 that, from experiments and/or actual use of the label engraving apparatus, is known to be a suitable temperature for engraving a label using the laser diode 112. A suitable temperature for engraving a unit lot number on a wafer using the laser diode 112 is, for example, about 24° C. to about 26° C., and preferably about 25° C.

As shown in FIG. 6, when the temperature of the laser diode 112 changes, the output power of the laser beam also changes (when input current is constant). Thus, when input current is constant, when the temperature of the laser diode 112 is maintained at the reference temperature, the laser beam emitted from the laser diode 112 has the reference energy level (and thus a reference output power) and may accurately engrave the label. The laser beam having the reference energy level, which is emitted from the laser diode 112, is provided to a projection member 160 via a fiber optic cable 105.

Referring now to FIG. 5, the heat-exchange member 150, the measuring member 120, and the light source member 110 may be placed in a rack 101 (i.e., in one rack). In the illustrated embodiment, the light source member 110 and the projection member 160 are electrically coupled via a fiber optic cable 105. The rack 101 and the processing member 130 are electrically connected through a data cable.

The projection member 160 is adapted to project the laser beam having the reference energy level onto the semiconductor substrate. In the illustrated embodiment, the projection member 160 comprises a laser resonator 161 and a scanner 165. The laser resonator 161 comprises a focusing lens 162, an oscillating mirror 163, and a beam expander 164. The scanner 165 comprises a galvo motor 166, a tiltable mirror 167, a focusing lens 168. The laser resonator 161 and the scanner 165 are substantially similar to a conventional laser resonator and a conventional scanner, respectively. Thus, further illustration and/or description of the laser resonator 161 and the scanner 165 is omitted herein.

Hereinafter, a process for engraving a label on a wafer, such as the type used to manufacture semiconductor devices, using the label engraving apparatus in accordance with an example embodiment of the present invention will be described in some additional detail.

When the wafer is prepared, a forward current is applied to the laser diode 112. The laser diode 112 emits a laser beam. When the laser diode 112 reaches a temperature of about 25° C., the laser beam is irradiated onto the wafer to engrave the label. In one example embodiment, the laser beam has a wavelength of about 600 nm to about 1,000 nm. The input current is stored in the memory module 131 of the processing member 130 just after the laser diode 112 emits the laser beam.

A photodetector associated with the wafer (not shown) collects a portion (e.g., a reflected portion) of the laser beam. A photocurrent from the photodetector corresponding to the optical energy of the laser beam collected in the photodetector is then generated. Next, the photocurrent is converted into a voltage that corresponds to the intensity of the laser beam.

As described previously, when any two of the three pieces of data used in characteristic graph 200 (i.e., input current, output power, and the temperature of the laser diode 112) are measured, the remaining piece of data may be calculated using the linear equation for the laser diode 112.

For example, as shown in FIG. 6, when the output power of the laser beam emitted from the laser diode 112 is about 1.2 mW (indicated by line \textcircled{1} of FIG. 6) and a constant current of about 30 mA is applied to the laser diode 112 (i.e., the laser diode 112 has an input current of about 30 mA, as indicated by line \textcircled{2} of FIG. 6); graph 200 of FIG. 6 shows that the laser diode 112 has a present temperature of about 30° C. However, when the desired output power for the laser beam is about 2.4 mW (indicated by line \textcircled{4} of FIG. 6) and an input current of about 30 mA (indicated by line \textcircled{3} of FIG. 6) is provided to the laser diode 112, graph 200 of FIG. 6 shows that the laser diode 112 has a target temperature of about 25° C. Thus, a difference between the present temperature and the target temperature is about 5° C. That is, the temperature compensation value for the laser diode 112 is about −5° C. The “target temperature” is the temperature that the laser diode 112 must achieve in order to generate a laser beam with the desired output power (while the input current is constant). Thus, as described previously, the present temperature may be obtained indirectly by calculating the present temperature of the laser diode 112 using characteristic graph 200 (of FIG. 6) (or using the calculation program) when the output power and the input power are measured.

A process for calculating the temperature compensation value of the laser diode 112 is carried out in the calculating module 135. Particularly, the present temperature of the laser diode 112 (obtained indirectly using the measured input current and output power as described above) is converted into a third electrical signal. Then, the third electrical signal is provided to the calculating module 135. Further, the target temperature for the laser diode 112 is converted into a fourth electrical signal. The fourth electrical signal is provided from the memory module 131 to the calculating module 135. The calculating module 135 calculates the difference between the target temperature, which is the reference temperature, and the present temperature, thereby calculating the temperature compensation value for the laser diode 112. The temperature compensation value is converted to a fifth electrical signal. The temperature compensation value is provided to the heat-exchanging member 150 to maintain the temperature of the laser diode 112 at the target temperature for the laser diode 112 (or adjust the temperature of the laser diode 112 to the target temperature).

In this example embodiment, after calculating the present temperature of the laser diode 112 in accordance with the output power of the laser beam emitted from the laser diode 112, the calculating module 135 compares the present temperature with the reference temperature to calculate the temperature compensation value for the laser diode 112. Alternatively, the temperature compensation value of the laser diode 112 may be obtained without calculating the present temperature of laser diode 112. Particularly, the temperature compensation value for the laser diode 112 may be calculated using the difference between the output power of the laser diode 112 at the present temperature (i.e., a present output power) and the output power of the laser diode 112 at the reference temperature (i.e., a reference output power). For example, as shown in FIG. 6, when the difference between the present output power (1.2 mW) and the reference output power (2.4 mW) is about 1.2 mW (2.4 mW-1.2 mW), the temperature compensation value for the laser diode 112 may be obtained using the 1.2 mW difference in output power. To obtain the temperature compensation value, after information relating to the output power of the laser beam and other information relating to the temperature compensation value is stored in the memory module 131, the calculating module 135 calculates the temperature compensation value in accordance with the information.

In accordance with example embodiments of the present invention, a laser beam having the reference energy level is continuously emitted from the laser diode 112 having the reference temperature. The laser beam is provided to the projection member 160 so that a path and an optical characteristic of the laser beam may be changed. The laser beam is irradiated onto an object such as a wafer to engrave a label on the object. In this case, the energy level of the laser beam is constantly maintained so that the laser beam has a constant wavelength. Thus, the problem of, for example, dot cracking due to variation of the energy level of the laser beam may be prevented.

In accordance with the present invention, the temperature of the laser diode is maintained at a constant level so that the laser diode may constantly emit a laser beam having an optimal energy level. Thus, a label may be accurately engraved on the semiconductor substrate using the label engraving apparatus of the present invention. Further, the occurrence of damage to a semiconductor substrate, such as cracked dots, may be reduced.

While example embodiments of the present invention have been described herein, the invention is not limited to the example embodiments disclosed. Rather, various modifications can be made to the example embodiments without departing from the scope of the present invention as claimed in the following claims.

What is claimed is:

1. A method of engraving a label on a wafer comprising:
i) measuring a present energy level of a laser beam emitted from a laser diode, wherein the present energy level corresponds to a present output power of the laser diode;
ii) calculating a temperature compensation value;
iii) adjusting a temperature of the laser diode in relation to a reference temperature and the temperature compensation value;
iv) irradiating the wafer With the laser beam from the laser diode, wherein a energy level of the laser beam corresponds to a reference output power; and
v) repeating steps i) through iv).

2. The method of claim 1, wherein the reference temperature is about 25° C.

3. The method of claim 1, wherein calculating the temperature compensation value comprises:
calculating a present temperature of the laser diode in accordance with the present output power and an input current;
calculating a difference between the present temperature and the reference temperature of the laser diode; and
providing the difference as the temperature compensation value.

4. The method of claim 3, wherein calculating the present temperature of the laser diode comprises:
providing the input current and the present output power to a calculation program; and
calculating the present temperature using the calculation program.

5. The method of claim 1, wherein calculating the temperature compensation value comprises:
calculating a difference between the present output power and the reference output power, wherein the reference output power is the output power of the laser beam emitted from the laser diode at the reference temperature; and
calculating the temperature compensation value in accordance with the difference.

6. The method of claim 1, wherein adjusting the present temperature of the laser diode to the reference temperature comprises:
cooling or heating the laser diode in accordance with the temperature compensation value.

7. The method of claim 1, wherein repeating the steps i) through iv) comprises:
repeating the steps i) through iv) at predetermined intervals.

8. The method of claim 1, wherein repeating the steps i) through iv) comprises:
repeating the steps i) through iv) continuously.

9. An apparatus adapted to engrave a label on a wafer, comprising:
a light source member comprising a laser diode adapted to emit a laser beam;
a measuring member adapted to measure a present energy level of the laser beam, wherein the present energy level corresponds to a present output power;
a processing member adapted to compare the present energy level with a reference energy level to calculate a temperature compensation value for the laser diode, wherein the reference energy level is an energy level of the laser beam emitted from the laser diode at a reference temperature;
a heat-exchanging member adapted to adjust a temperature of the laser diode relative to the reference temperature and the temperature compensation value; and
a projection member adapted to project the laser beam onto the wafer.

10. The apparatus of claim 9, wherein the processing member comprises:
a memory module adapted to store an input current and a calculation program; and
a calculating module adapted to calculate the temperature compensation value in accordance with a difference between a present temperature of the laser diode and the reference temperature,
wherein the present temperature is calculated using the calculation program in relation to the input current and the present output power.

11. The apparatus of claim 10, wherein the reference temperature is about 25° C.

12. The apparatus of claim 9, wherein the light source member further comprises:
an internal power supply adapted to apply an operating voltage to the laser diode; and
a controller adapted to control an amount of current provided by the internal power supply to the laser diode.

13. The apparatus of claim 9, wherein the measuring member comprises a photometer adapted to collect a portion of the laser beam, to output a photocurrent corresponding to the present energy level of the laser beam, and to convert the photocurrent into a voltage.

14. The apparatus of claim 9, wherein the heat-exchanging member comprises a chiller and a heating pump positioned adjacent to the light source member.
